(19) United States
(12) Patent Application Publication
(10) Pub. No.: US 2023/0369505 A1
(43) Pub. Date: Nov. 16, 2023

(54) VERTICAL TRANSISTORS AND METHODS FOR FORMING THE SAME

(71) Applicant: Tokyo Electron Limited, Tokyo (JP)

(72) Inventors: Mark I. Gardner, Albany, NY (US); H. Jim Fulford, Albany, NY (US); Partha Mukhopadhyay, Albany, NY (US)

(73) Assignee: Tokyo Electron Limited, Tokyo (JP)

(21) Appl. No.: 17/741,069

(22) Filed: May 10, 2022

(51) Int. Cl. H01L 29/786; H01L 27/092; H01L 29/417; H01L 29/76; H01L 29/66

(52) U.S. Cl. CPC H01L 29/78642; H01L 27/0922; H01L 29/41733; H01L 29/7606; H01L 29/66969

(57) ABSTRACT

A semiconductor device may include a transistor structure. The transistor structure may include a metal structure extending along a vertical direction; a gate dielectric layer around the metal structure; a channel layer around the gate dielectric layer; a first metal electrode disposed below the metal structure and in electrical contact with a first end of the channel layer; a second metal electrode disposed above the metal structure and in electrical contact with a second end of the channel layer; and a third metal electrode disposed above and in electrical contact with the metal structure.

### TECHNICAL FIELD

The present disclosure relates generally to the field of manufacturing transistors.

### BACKGROUND

Scaling of features in integrated circuits has been a driving force behind the growing semiconductor industry for the past decades. Scaling to smaller features enables an increased density of functional units on a limited substrate surface of a semiconductor chip. For example, shrinking transistor size allows for an increase in the number of memory devices incorporated on a chip, resulting in increased capacity in the manufacture of products. However, driving ever increasing capacity is not without problems. The necessity to optimize the performance of each device becomes increasingly important.

### SUMMARY

One aspect of the present disclosure may be directed to a semiconductor device. The semiconductor device may include a transistor structure. The transistor structure may include a metal structure extending along a vertical direction; a gate dielectric layer around the metal structure; a channel layer around the gate dielectric layer; a first metal electrode disposed below the metal structure and in electrical contact with a first end of the channel layer; a second metal electrode disposed above the metal structure and in electrical contact with a second end of the channel layer; and a third metal electrode disposed above and in electrical contact with the metal structure.

The semiconductor device may further include a second transistor structure disposed above the transistor structure. The second transistor structure may include a second metal structure extending along the vertical direction; a second gate dielectric layer around the second metal structure; a second channel layer around the second gate dielectric layer; a fourth metal electrode disposed below the second metal structure and above the first metal structure, and in electrical contact with a first end of the second channel layer; a fifth metal electrode disposed above the second metal structure and in electrical contact with a second end of the second channel layer; and a sixth metal structure disposed above and in electrical contact with the second metal structure. The channel layer and second channel layer may have respectively different conductive types.

The first metal electrode and second metal electrode may each be formed in a ring-based shape. The second metal electrode may extend around the third metal electrode.

The channel layer may further include a two-dimensional material around the gate dielectric layer; and a conductive oxide material around the two-dimensional material. The two-dimensional material may have a vertical portion and a horizontal portion, both of which are in physical contact with the conductive oxide material. The channel layer may electrically connect to the first metal electrode with the horizontal portion of the two-dimensional material, and electrically connect to the second metal electrode with both the conductive oxide and the vertical portion of the two-dimensional material.

The present solution may utilize 2D materials for forming transistor channels. 2D materials can include, for example, but are not limited to, WS2, WSe2, WTe2, MoS2, MoSe2, MoTe2, HfS2, ZrS2, and TiS2, GaSe, InSe, phosphorene, and other similar materials. These materials can be deposited by an atomic layer deposition (ALD) process and may be about 5-15 angstroms thick, the thinness lending to their name—2D material. 2D material layer can, depending on the material and design, and can have a broader range of thicknesses, such as between 0.2 nm and 3 nm, for example. 2D materials may be annealed during or after the device formation process to recrystallize or grow the crystals and thereby improve electrical characteristics. 2D materials, for example, can be electrically conductive.

Additionally or alternatively, the channels may comprise one or more semiconductive-behaving materials, which may be formed using certain elements that, when combined with oxygen, form a new material that exhibits semiconductive behavior. For example, the semiconductive behaving material can be “turned off” and can have a low or practically no off-state leakage current, and can be “turned on” and become highly conductive when voltage is applied. Example materials to create an n-type channel for example include, but are not limited to, In₂O₃, SnO₂, In GaZnO, and ZnO. Example materials that can be used to create a p-type channel may be formed utilizing, for example, SnO. These materials may be further doped to improve the electrical characteristics. These materials may also be referred to as conductive oxides or semiconductive behaving oxides for the purposes of this discussion.

The channel layer may further include a two-dimensional material around the gate dielectric layer; and a dielectric material around the two-dimensional material. The two-dimensional material may have a vertical portion and a horizontal portion, both of which are in physical contact with the dielectric material. The channel layer may electrically connect to the first metal electrode with the horizontal portion of the two-dimensional material, and electrically connect to the second metal electrode with the vertical portion of the two-dimensional material.

Another aspect of the present disclosure may be directed to a semiconductor device. The semiconductor device may include a transistor structure. The transistor structure may include a metal structure extending along a vertical direction; a gate dielectric layer around the metal structure; a channel layer around the gate dielectric layer; a first metal electrode formed in a first ring-based shape, wherein a top surface of the first metal electrode is in electrical contact with a first end of the channel layer; a second metal electrode formed in a second ring-based shape, wherein a bottom surface of the second metal electrode is in electrical contact with a second end of the channel layer; and a third metal electrode surrounded by the second metal structure and in electrical contact with the metal structure.

The channel layer may further include a two-dimensional material around the gate dielectric layer; and a conductive oxide material around the two-dimensional material. The two-dimensional material may have a vertical portion and a horizontal portion, both of which are in physical contact with the conductive oxide. The channel layer may electrically connect to the first metal electrode with the horizontal portion of the two-dimensional material, and electrically connect to the second metal electrode with the vertical portion of the two-dimensional material.

The channel layer may further include a two-dimensional material around the gate dielectric layer; and a dielectric material around the two-dimensional material. The channel layer may electrically connect to the first metal electrode with the horizontal portion of the two-dimensional material, and electrically connect to the second metal electrode with the vertical portion of the two-dimensional material.

Yet another aspect of the present disclosure may be directed to a method for fabricating semiconductor devices. The method may include: forming a first metal electrode on a substrate; forming a metal structure surrounded by the first metal electrode, wherein the metal structure extends along a vertical direction; forming a gate dielectric layer around the metal structure; forming a channel layer around the gate dielectric layer, wherein a first end of the channel layer is in electrical contact with the first metal electrode; forming a second metal electrode above the metal structure, wherein a second end of the channel layer is in electrical contact with the second metal structure; and forming a third metal electrode surrounded by the second metal electrode, wherein the third metal electrode is in electrical contact with the metal structure.

The first metal electrode and second metal electrode may each be formed in a ring-based shape.

The step of forming a channel layer may include depositing a two-dimensional material over the substrate; depositing a conductive oxide material over the two-dimensional material; and directionally etching the two-dimensional material and the conductive oxide to form the channel layer.

The step of forming a channel layer may include depositing a two-dimensional material over the substrate; depositing a dielectric material over the two-dimensional material; and directionally etching the two-dimensional material and the dielectric material to form the channel layer.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect can be combined with other aspects. Aspects can be implemented in any convenient form. As used in the specification and in the claims, the singular form of ‘a’, ‘an’, and ‘the’ include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of simplicity, not every component may be labeled in every drawing. In the drawings:

FIG. 1 illustrates a flow chart of an example method for making a semiconductor device, in accordance with some embodiments.

FIGS. 2A and 2B illustrate a top view and a cross-sectional view of a semiconductor device, respectively, during various fabrication stages, made by the method of FIG. 1, in accordance with some embodiments.

FIGS. 3A and 3B illustrate a top view and a cross-sectional view of a semiconductor device, respectively, during various fabrication stages, made by the method of FIG. 1, in accordance with some embodiments.

FIGS. 4A and 4B illustrate a top view and a cross-sectional view of a semiconductor device, respectively, during various fabrication stages, made by the method of FIG. 1, in accordance with some embodiments.

FIGS. 5A and 5B illustrate a top view and a cross-sectional view of a semiconductor device, respectively, during various fabrication stages, made by the method of FIG. 1, in accordance with some embodiments.

FIGS. 6A and 6B illustrate a top view and a cross-sectional view of a semiconductor device, respectively, during various fabrication stages, made by the method of FIG. 1, in accordance with some embodiments.

FIGS. 7A and 7B illustrate a top view and a cross-sectional view of a semiconductor device, respectively, during various fabrication stages, made by the method of FIG. 1, in accordance with some embodiments.

FIGS. 8A and 8B illustrate a top view and a cross-sectional view of a semiconductor device, respectively, during various fabrication stages, made by the method of FIG. 1, in accordance with some embodiments.

FIGS. 9A and 9B illustrate a top view and a cross-sectional view of a semiconductor device, respectively, during various fabrication stages, made by the method of FIG. 1, in accordance with some embodiments.

FIGS. 10A and 10B illustrate a top view and a cross-sectional view of a semiconductor device, respectively, during various fabrication stages, made by the method of FIG. 1, in accordance with some embodiments.

FIGS. 11A and 11B illustrate a top view and a cross-sectional view of a semiconductor device, respectively, during various fabrication stages, made by the method of FIG. 1, in accordance with some embodiments.

FIGS. 12A and 12B illustrate perspective views of the semiconductor device corresponding to the top views and cross-sectional views shown in FIGS. 2A to 11B, in accordance with some embodiments.

FIGS. 13A and 13B illustrate a top view and a cross-sectional view of a semiconductor device, respectively, during various fabrication stages, made by the method of FIG. 1, in accordance with some embodiments.

FIGS. 14A and 14B illustrate a top view and a cross-sectional view of a semiconductor device, respectively, during various fabrication stages, made by the method of FIG. 1, in accordance with some embodiments.

FIGS. 15A and 15B illustrate a top view and a cross-sectional view of a semiconductor device, respectively, during various fabrication stages, made by the method of FIG. 1, in accordance with some embodiments.

FIGS. 16A and 16B illustrate a top view and a cross-sectional view of a semiconductor device, respectively, during various fabrication stages, made by the method of FIG. 1, in accordance with some embodiments.

FIGS. 17A and 17B illustrate a top view and a cross-sectional view of a semiconductor device, respectively, during various fabrication stages, made by the method of FIG. 1, in accordance with some embodiments.

FIGS. 18A and 18B illustrate a top view and a cross-sectional view of a semiconductor device, respectively, during various fabrication stages, made by the method of FIG. 1, in accordance with some embodiments.

FIGS. 19A and 19B illustrate perspective views of the semiconductor device corresponding to the top views and cross-sectional views shown in FIGS. 13A to 18B, in accordance with some embodiments.

FIGS. 20A and 20B illustrate a top view and a cross-sectional view of a semiconductor device, respectively, during various fabrication stages, made by the method of FIG. 1, in accordance with some embodiments.

FIGS. 21A and 21B illustrate a top view and a cross-sectional view of a semiconductor device, respectively, during various fabrication stages, made by the method of FIG. 1, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Disclosed herein are embodiments related to one or more transistor structures formed based on a vertical metal structure. In some embodiments, the vertical metal structure may serve as a mandrel for forming a (e.g., vertical) transistor structure and operatively function as the gate of such a transistor structure. Based on such a vertical metal structure, advantageously, the transistor structures, as disclosed herein, may be formed as channel-all-around (CAA) or channel around gate (CAG) transistor structures, with a channel layer wrapping around the vertical metal gate structure. In one aspect, any number of the disclosed vertical metal structures can be laterally (e.g., side-by-side) arranged with each other and vertically stacked on top of one another, thereby forming an array of transistor structures having improved characteristics in an area efficient manner. For example, with two different conductive types of the disclosed transistor structure stacked on top of one another, a complementary field-effect-transistor structure can be formed. In one aspect, with the vertical metal structure serving as a mandrel, an arrangement of the channel layer to be formed around the mandrel can be flexibly configured. For example, the channel layer can have a single material (e.g., a conductive oxide material) or plural materials (e.g., a conductive oxide material wrapping around a two-dimensional (2D) material). In general, conductive oxide materials/2D materials can allow significant boost in performance relative to silicon (Si), such that transistor structures disclosed herein may have improved performances or characteristics (e.g., improved transconductance (gm), improved gain bandwidth (Ft), improved saturation current (Idsat), etc.).

Reference will now be made to the figures, which for the convenience of visualizing the 3D fabrication techniques described herein, illustrate a substrate undergoing a process flow in both top and cross-sectional views. Unless expressly indicated otherwise, each Figure represents one (or a set) of fabrication steps in a process flow for manufacturing the devices described herein. In the top and cross-sectional views of the Figures, connections between conductive layers or materials may be shown. However, it should be understood that these connections between various layers and masks are merely illustrative, and are intended to show a capability for providing such connections and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, although certain figures show various layers defining transistor structures or other electric structures in a circular configuration, other shapes are also contemplated, and indeed the techniques described herein may be implemented in any shape or geometry.

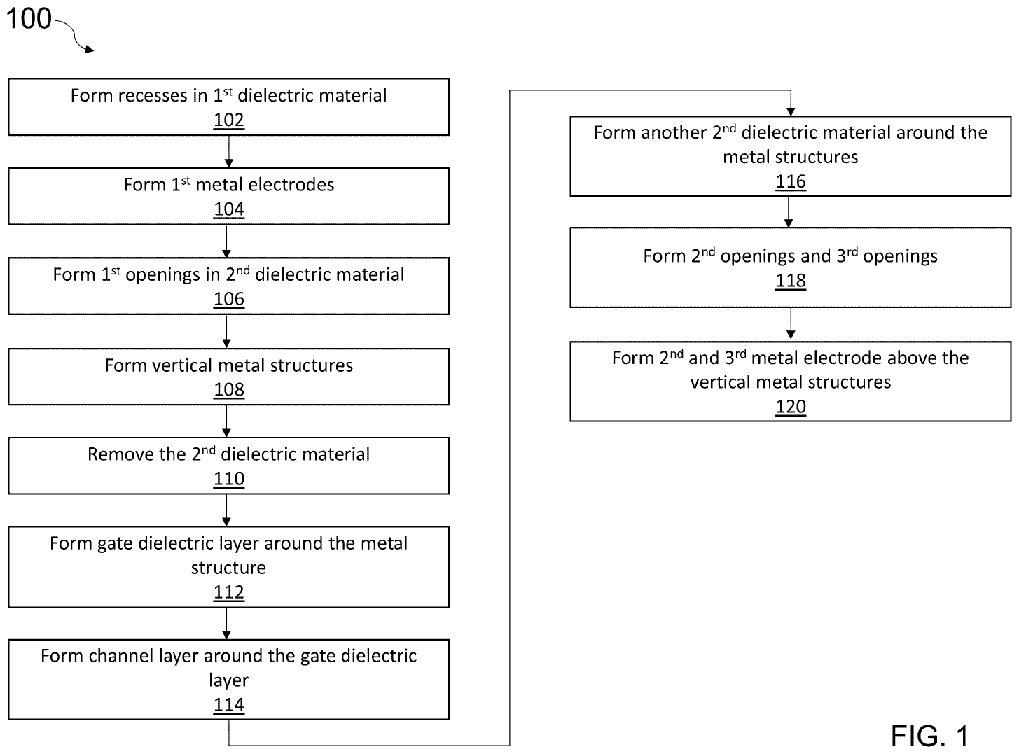

FIG. 1 illustrates a flowchart of an example method 100 for forming a semiconductor device (e.g., a transistor) based on a vertical metal structure/mandrel. For example, the transistor may be a vertical transistor with a channel layer wrapping around or otherwise surrounding the vertical metal structure that also operatively functions as a gate of the transistor. It is noted that the method 100 is merely an example, and is not intended to limit the present disclosure. Accordingly, it is understood that additional operations may be provided before, during, and after the method 100 of FIG. 1, and that some other operations may only be briefly described herein.

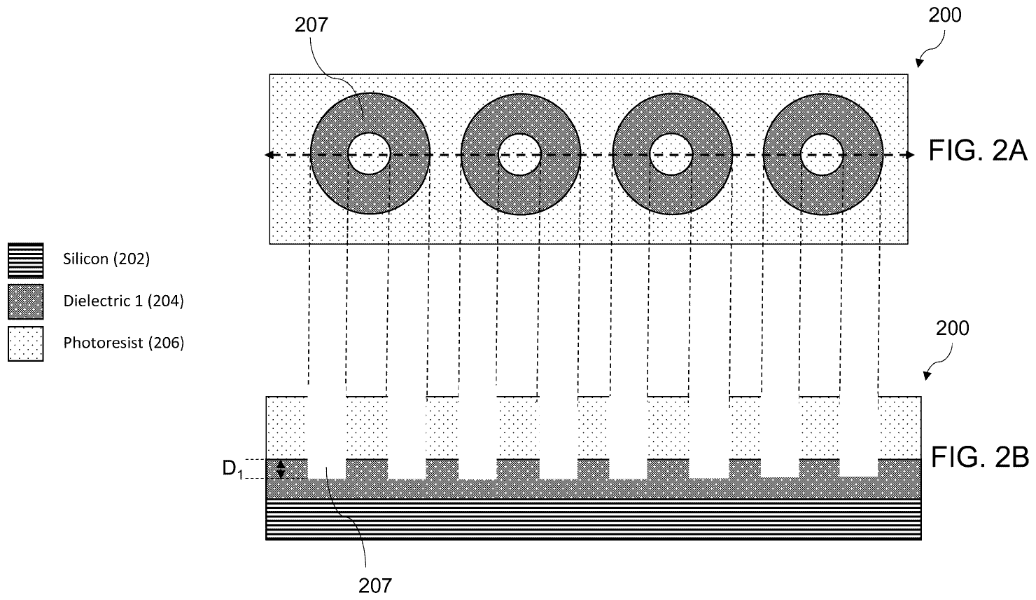

In various embodiments, operations of the method 100 may be associated with top views and cross-sectional views of an example semiconductor device 200 at various fabrication stages as shown in FIGS. 2A to 11A and FIGS. 2B to 11B, respectively, which will be discussed in further detail below. It should be understood that the semiconductor device 200, shown in FIGS. 2A to 11B, may include a number of other devices such as inductors, fuses, capacitors, coils, etc., while remaining within the scope of the present disclosure.

In brief overview, the method 100 starts with operation 102 of forming a number of recesses in a first dielectric material. The method 100 continues to operation 104 of forming a number of first metal electrodes in the recesses, respectively. In various embodiments, the first metal electrodes may each be formed in a ring-based shape. The method 100 proceeds to operation 106 of forming a number of first openings in a second dielectric material. The method 100 proceeds to operation 108 of forming a number of vertical metal structures in the openings, respectively. The vertical metal structure may be surrounded by the first metal electrode (when viewed from the top). The method 100 proceeds to operation 110 of removing the second dielectric material. The method 100 proceeds to operation 112 of forming a gate dielectric layer around each of the vertical metal structures. The method 100 proceeds to operation 114 of forming a channel layer around the gate dielectric layer. The method 100 proceeds to operation 116 of forming another second dielectric material around the vertical metal structures. The method 100 proceeds to operation 118 of forming a number of second openings and a number of third openings. The method 100 proceeds to operation 120 of forming a number of second metal electrodes and a number of third metal electrodes above the vertical metal structures. In various embodiments, the second metal electrode may also be formed in the ring-based shape. In various embodiments, the second metal electrode may surround or otherwise enclose the third metal electrode.

Corresponding to operation 102 of FIG. 1, FIG. 2A is a top view of the semiconductor device 200 in which a number of recesses 207 are formed on a substrate 202 at one of the various stages of fabrication, and FIG. 2B is a corresponding cross-sectional view of the semiconductor device 200, in accordance with various embodiments.

As shown in FIG. 2B, a first dielectric material 204 is formed over the substrate 202, and a patternable layer (e.g., a photoresist material) 206 is further formed over the first dielectric material 204. The recesses 207 are formed to extend into the first dielectric material 204 with a certain depth, D₁. In various embodiments, the recesses 207 may each be formed in a closed-loop shape, e.g., a ring-based shape as shown in the top view of FIG. 2A. Further, the different recesses 207 may be laterally spaced apart from one another, which allows the recesses 207 to define the footprints of respective transistors. In various embodiments, the recesses 207 may be formed by one or more etching process performed on the first dielectric material 204 based on the patternable layer 206. For example, the patternable layer 206 may be first formed over the first dielectric material 204 (each of which is deposited as a blanket layer), the patternable layer 206 may be etched to form a number of patterns, and those patterns formed in the patternable layer 206 are then transferred to the first dielectric material 204 through at least one etching process. The etching process forming the recesses 207 may be anisotropic and/or isotropic.

In various embodiments, the substrate 202 may be any semiconductor, insulator or conductor. In some embodiments, the substrate 202 comprises a semiconductor material such as silicon or germanium. The substrate 202 may also include a compound semiconductor such as silicon carbide, gallium arsenic, indium arsenide, and indium phosphide. The substrate 202 may include an alloy semiconductor such as silicon germanium, silicon germanium carbide, gallium arsenic phosphide, and gallium indium phosphide. In one embodiment, the substrate 202 includes an epitaxial layer. For example, the substrate 202 may have an epitaxial layer overlying a bulk semiconductor. Furthermore, the substrate 202 may include a semiconductor-on-insulator (SOI) structure. For example, the substrate 202 may include a buried oxide (BOX) layer formed by a process such as separation by implanted oxygen (SIMOX) or other suitable technique, such as wafer bonding and grinding.

In various embodiments, the first dielectric material 204 includes at least one insulation material, which can electrically isolate neighboring active structures (e.g., metal electrodes which will be formed subsequently) from each other. The insulation material may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used. An anneal process may be performed once the insulation material is formed. Following the deposition of the first dielectric material 204 and the patternable layer 206 with patterns, a dry etch or a wet etch process including, e.g., dilute hydrofluoric (DHF) acid, may be performed to etch the first dielectric material 204 to form the recesses 207.

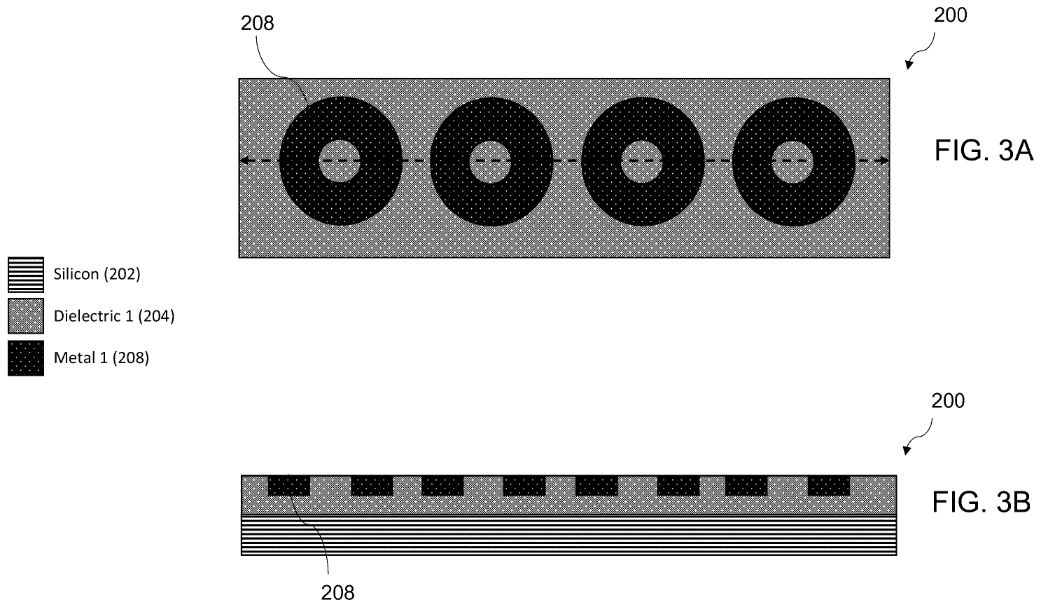

Corresponding to operation 104 of FIG. 1, FIG. 3A is a top view of the semiconductor device 200 in which a number of first metal electrodes 208 are formed in the substrate 202 at one of the various stages of fabrication, and FIG. 3B is a corresponding cross-sectional view of the semiconductor device 200, in accordance with various embodiments.

After forming the recesses 207, the patternable layer 206 is removed. Next, at least the recesses 207 are filled with a first metal material. The first metal material may include copper, aluminum, or the like. The first metal material may be deposited by CVD, physical vapor deposition (PVD), atomic layer deposition (ALD), and/or other suitable metal filling process. Next, a polishing or planarization process (e.g., a chemical mechanical polishing (CMP) process) may be performed to remove excessive first metal material until a coplanar surface is formed by the first metal electrodes 208 and the first dielectric material 204. In various embodiments, the first metal electrodes 208 can inherit the dimensions and profiles of the recesses 207, and thus, the first metal electrodes 208 may also have a ring-based shape, as shown in the top view of FIG. 3A.

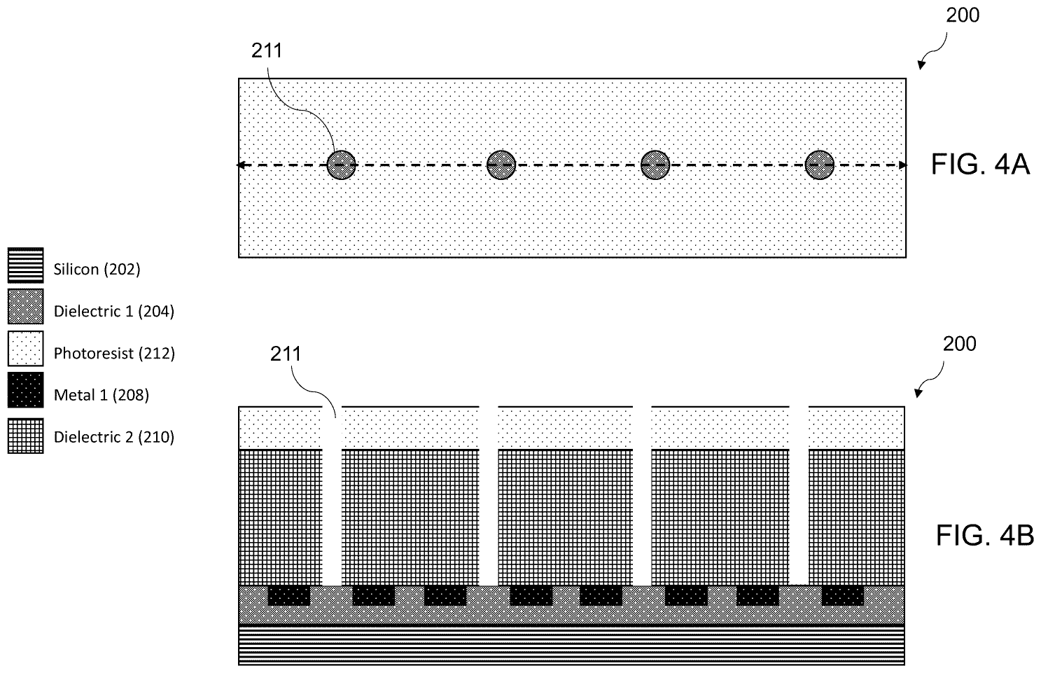

Corresponding to operation 106 of FIG. 1, FIG. 4A is a top view of the semiconductor device 200 in which a number of first openings 211 are formed through a second dielectric material 210 disposed over the substrate 202 at one of the various stages of fabrication, and FIG. 4B is a corresponding cross-sectional view of the semiconductor device 200, in accordance with various embodiments.

As shown in FIG. 4B, a second dielectric material 210 is formed over the substrate 202, and a patternable layer (e.g., a photoresist material) 212 is further formed over the second dielectric material 210. The first openings 211 are formed to extend through the second dielectric material 210 and stop at the first dielectric material 204. In various embodiments, the first openings 211 may each be formed inside the footprint of a corresponding one of the first metal electrodes 208, as shown in the cross-sectional view of FIG. 4A. In various embodiments, the first openings 211 may be formed by one or more etching process performed on the second dielectric material 210 based on the patternable layer 212. For example, the patternable layer 212 may be first formed over the second dielectric material 210 (each of which is deposited as a blanket layer), the patternable layer 212 may be etched to form a number of patterns, and those patterns formed in the patternable layer 212 are then transferred to the second dielectric material 210 through at least one etching process. The etching process forming the first openings 211 may be anisotropic and/or isotropic.

In various embodiments, the second dielectric material 210 may have an etching selectivity with respect to the first dielectric material 204, thereby allowing the etching process to form the first openings 211 can be stopped at the first dielectric material 204. The second dielectric material 210 may be an oxide, such as silicon oxide, a nitride, the like, or combinations thereof, and may be formed by a high density plasma chemical vapor deposition (HDP-CVD), a flowable CVD

(FCVD) (e.g., a CVD-based material deposition in a remote plasma system and post curing to make it convert to another material, such as an oxide), the like, or combinations thereof.

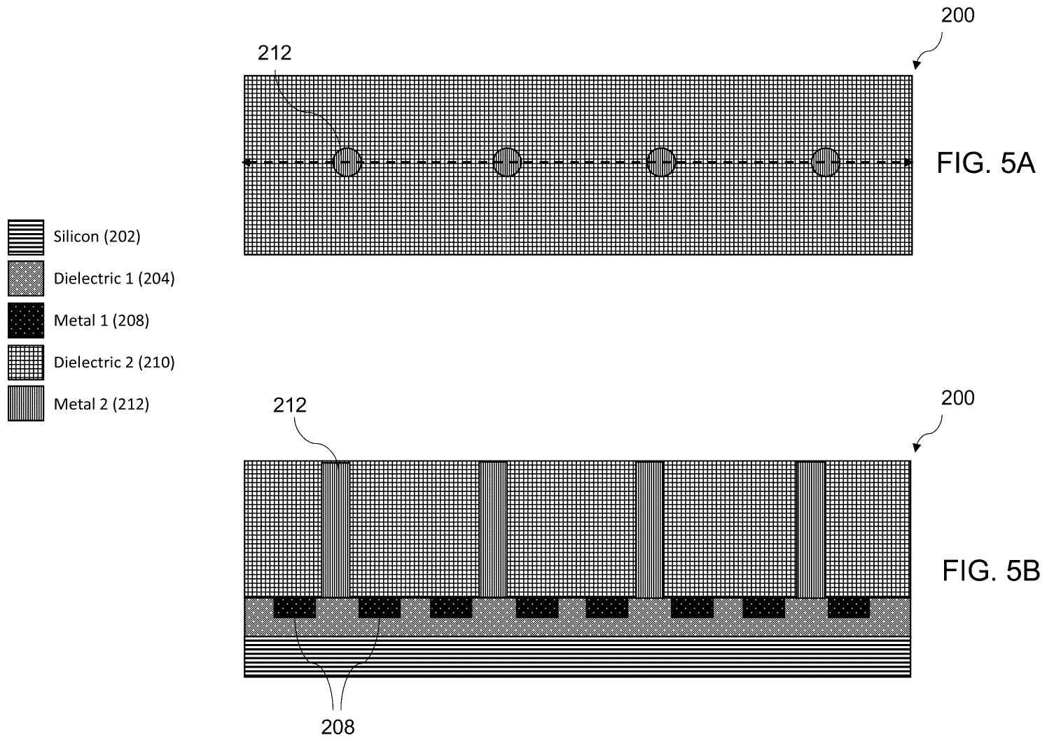

Corresponding to operation 108 of FIG. 1, FIG. 5A is a top view of the semiconductor device 200 in which a number of metal structures 212 are formed through the second dielectric material 210 at one of the various stages of fabrication, and FIG. 5B is a corresponding cross-sectional view of the semiconductor device 200, in accordance with various embodiments.

After forming the first openings 211, the patternable layer 212 is removed. Next, at least the first openings 211 are filled with a second metal material. In various embodiments, the second metal material may include a work function layer. For example, the second metal material may be a p-type work function layer, an n-type work function layer, multi-layers thereof, or combinations thereof. Example p-type work function layers may include TiN, TaN, Ru, Mo, Al, WN, ZrSi2, MoSi2, TaSi2, NiSi2, WN, other suitable p-type work function materials, or combinations thereof. Example n-type work function layers may include Ti, Ag, TaAl, TaAlC, TiAlN, TaC, TaCN, TaSiN, Mn, Zr, other suitable n-type work function materials, or combinations thereof. The work function layer(s) may be deposited by CVD, physical vapor deposition (PVD), ALD, and/or other suitable process.

Following the deposition of the second metal material, a polishing or planarization process (e.g., a chemical mechanical polishing (CMP) process) may be performed to remove excessive second metal material until a coplanar surface is formed by the metal structures 212 and the second dielectric material 210. In various embodiments, the metal structures 212 can inherit the dimensions and profiles of the first openings 211, and thus, the metal structures 212 may also extend through the second dielectric material 210 and have its sidewalls enclosed by the inner sidewall of the corresponding first metal electrode 208, as shown in the cross-sectional view of FIG. 5B.

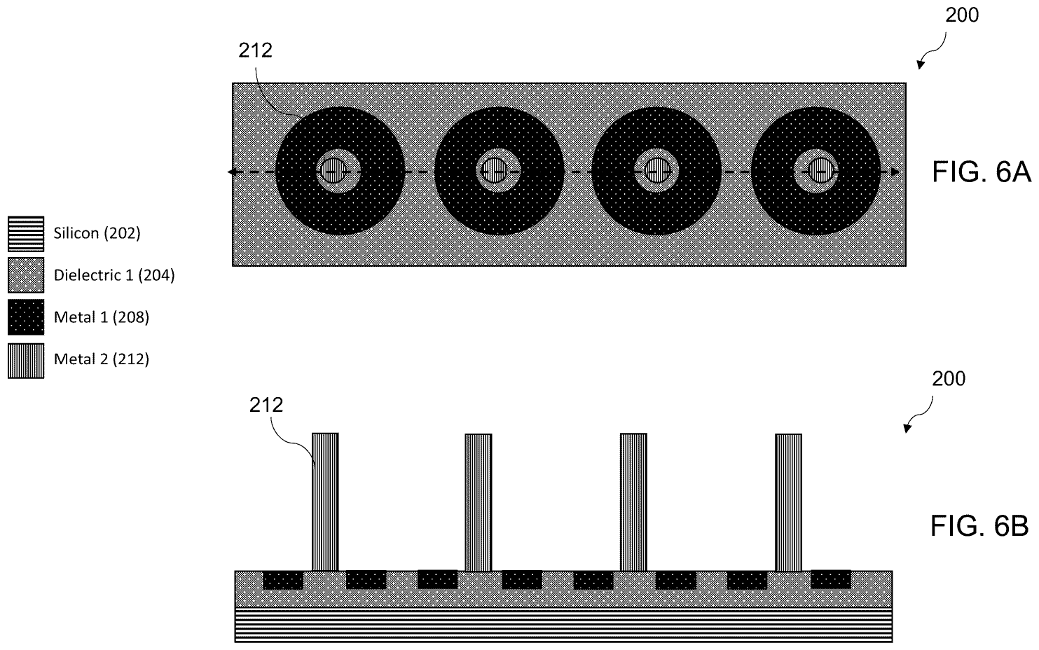

Corresponding to operation 110 of FIG. 1, FIG. 6A is a top view of the semiconductor device 200 in which the second dielectric material 210 is removed at one of the various stages of fabrication, and FIG. 6B is a corresponding cross-sectional view of the semiconductor device 200, in accordance with various embodiments. As mentioned above, the first dielectric material 204 has an etching selectivity with respect to the second dielectric material 210. Accordingly, after forming the metal structures 212, the second dielectric material 210 is removed while leaving the first dielectric material 204 substantially intact. As shown in FIG. 6B, the top surface and sidewalls of each of the metal structures 212 can be exposed, i.e., protruding out of the first dielectric material 204.

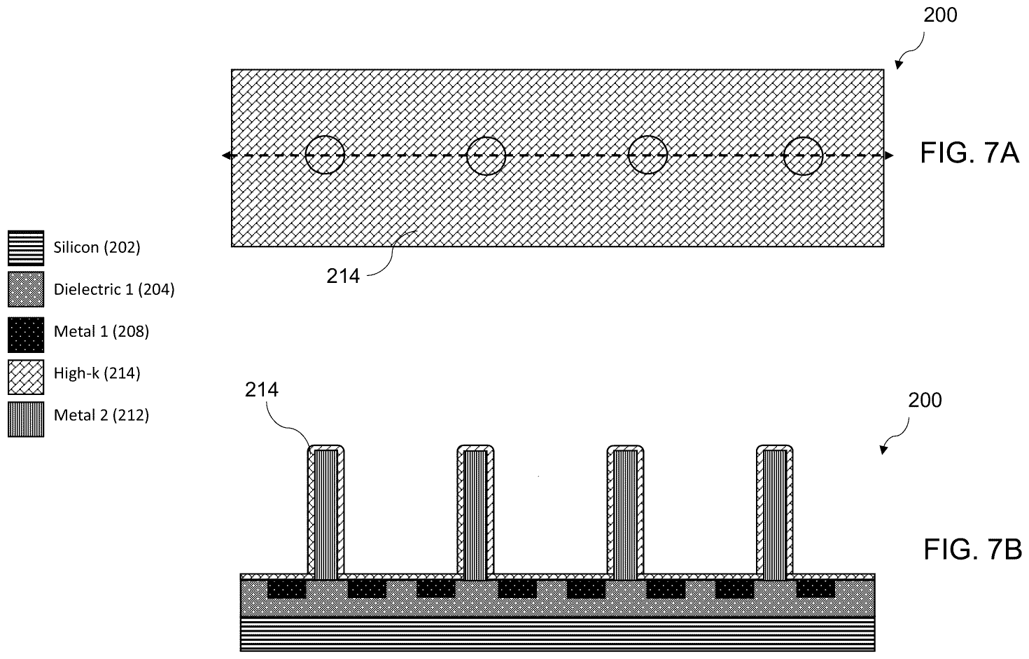

Corresponding to operation 112 of FIG. 1, FIG. 7A is a top view of the semiconductor device 200 in which a gate dielectric layer 214 is formed over the metal structures 212 at one of the various stages of fabrication, and FIG. 7B is a corresponding cross-sectional view of the semiconductor device 200, in accordance with various embodiments.

In various embodiments, the gate dielectric layer 214 is deposited over the workpiece, e.g., as a blanket layer. For example in FIG. 7B, the gate dielectric layer 214 can overlay the top surface of each of the metal structures 212 and extend along the sidewalls of each of the metal structures 212. The gate dielectric layer 214 may be formed of a single high-k dielectric material, multiple different high-k dielectric materials, or multiple similar high-k dielectric materials. Example high-k dielectric materials include a metal oxide or a silicate of Hf, Al, Zr, La, Mg, Ba, Ti, Pb, and combinations thereof. The gate dielectric layer 214 can be deposited using any suitable method, including, for example, molecular beam deposition (MBD), atomic layer deposition (ALD), PECVD, and the like. In some embodiments, the gate dielectric layer 214 may optionally include a substantially thin oxide (e.g., SiOx) layer.

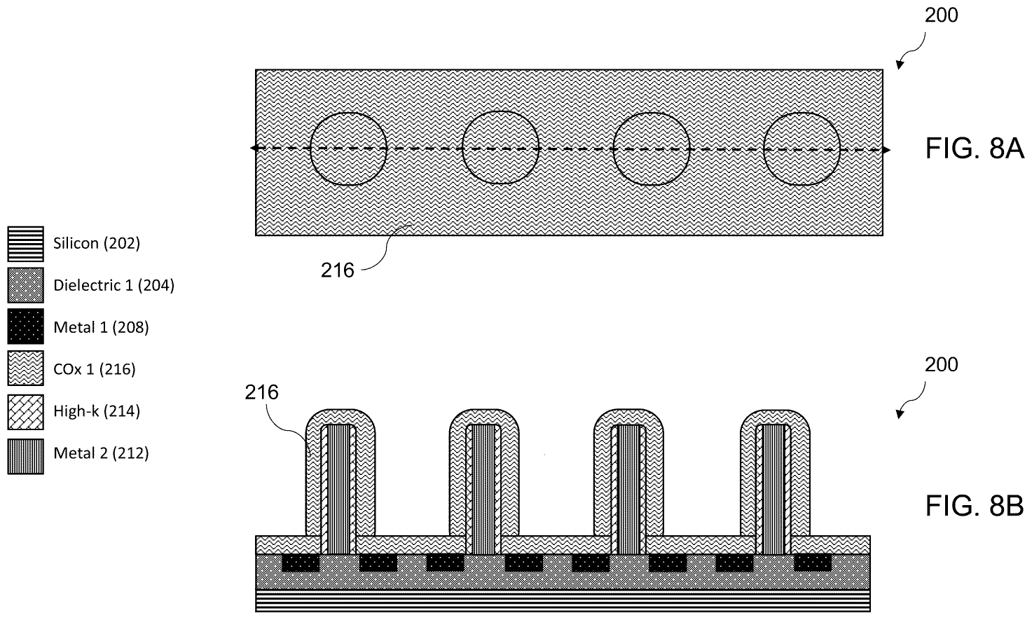

Corresponding to operation 114 of FIG. 1, FIG. 8A is a top view of the semiconductor device 200 in which a conductive oxide layer 216 is formed over the metal structures 212 at one of the various stages of fabrication, and FIG. 8B is a corresponding cross-sectional view of the semiconductor device 200, in accordance with various embodiments. The conductive oxide layer 216 may be one of various implementations of the channel layer formed around the metal structure 212.

Prior to depositing the conductive oxide layer 216, a directional (e.g., vertical) etching process may be performed to remove portions of the gate dielectric layer 214 that are disposed over the top surface of the metal structures 212 and over the coplanar surface formed by the first dielectric material 204 and the first metal electrodes 208. In various embodiments, the conductive oxide layer 216 may be formed with a relatively thin thickness, thereby allowing the conductive oxide layer 216 to form as a liner that can also extend along the sidewalls of the metal structures 212. Subsequently to forming the conductive oxide layer 216 (as a blanket layer), another directional (e.g., vertical) etching process may be performed to remove portions of the conductive oxide layer 216 that are disposed over the top surface of the metal structures 212 and over the coplanar surface formed by the first dielectric material 204 and the first metal electrodes 208. As such, the conductive oxide layer 216 (after being patterned) may surround the corresponding metal structure 212 with the corresponding gate dielectric layer 214 interposed therebetween.

In various embodiments, the patterned gate dielectric layer 214 and the patterned conductive oxide layer 216 may operatively function as the gate dielectric and the channel of a corresponding transistor, respectively. Example materials of the conductive oxide layer 216 includes, but are not limited to, indium gallium zinc oxide (IGZO), indium tin oxide (ITO), indium zinc oxide (IZO), indium tungsten oxide (IWO), or combinations thereof. In some embodiments, the conductive oxide layer 216 may be formed using, for example, CVD, PECVD, LPCVD, and the like. Further, the conductive oxide layer 216 may be doped through one or more annealing processes to have a certain conductive type, e.g., n-type or p-type.

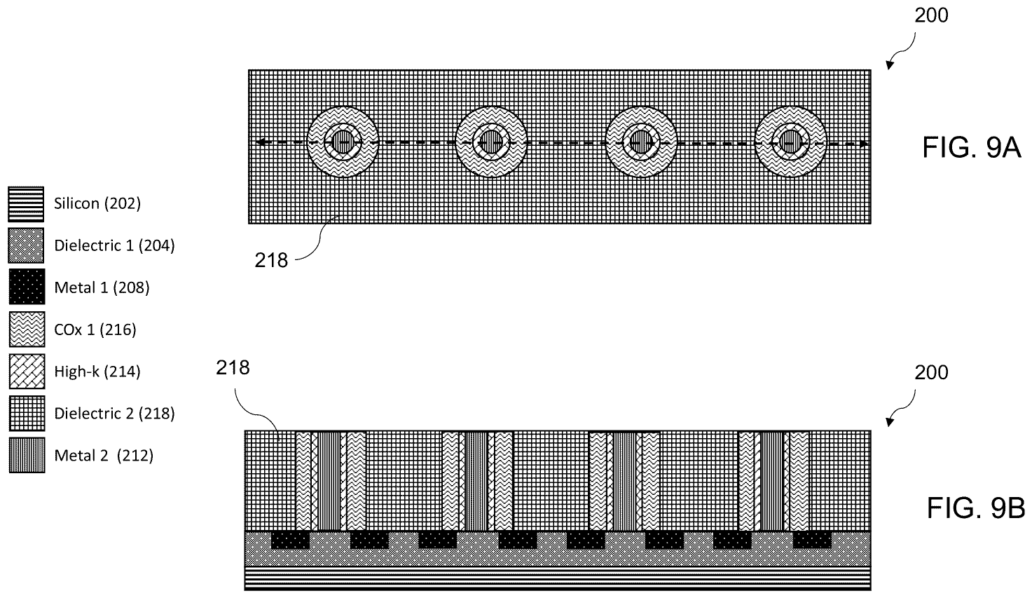

Corresponding to operation 116 of FIG. 1, FIG. 9A is a top view of the semiconductor device 200 in which another second dielectric material 218 is formed over the workpiece at one of the various stages of fabrication, and FIG. 9B is a corresponding cross-sectional view of the semiconductor device 200, in accordance with various embodiments.

Following the patterning of the conductive oxide layer 216, the second dielectric material 218 is deposited over the workpiece (e.g., filling the space between adjacent metal structures 212 and overlaying the metal structures 212), followed by a CMP process. As such, a coplanar surface may be formed by the metal structures 212, the (patterned) gate dielectric layer 214, the (patterned) conductive oxide layer 216, and the second dielectric material 218, as shown in the cross-sectional view of FIG. 9B. In various embodiments, the second dielectric material 218 may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof.

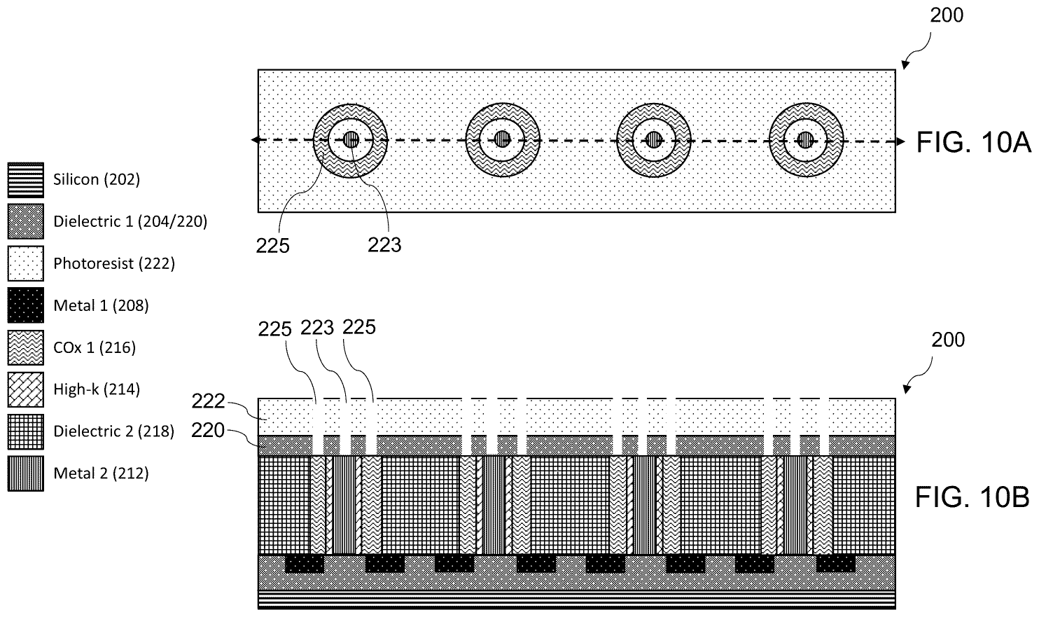

Corresponding to operation 118 of FIG. 1, FIG. 10A is a top view of the semiconductor device 200 in which a number of second openings 225 and a number of third openings 223 are formed through another first dielectric material 220 disposed over the workpiece at one of the various stages of fabrication, and FIG. 10B is a corresponding cross-sectional view of the semiconductor device 200, in accordance with various embodiments.

As shown in FIG. 10B, the first dielectric material 220 is formed over the second dielectric material 218, and a patternable layer (e.g., a photoresist material) 222 is further formed over the first dielectric material 220. The openings 223 and 225 are formed to extend through the first dielectric material 220 and stop at the metal structure 212 and the conductive oxide layer 216, respectively. In various embodiments, the third openings 223 may each be formed in a closed-loop profile (e.g., a ring-based shape), and the second openings 225 may each be formed inside a corresponding one of the third openings 223, as shown in the top view of FIG. 10A. Alternatively stated, an inner sidewall of the third opening 223 is enclosed by an inner sidewall of the corresponding second opening 225. In various embodiments, the openings 223-225 may be formed by one or more etching process performed on the first dielectric material 220 based on the patternable layer 222. For example, the patternable layer 222 may be first formed over the first dielectric material 220 (each of which is deposited as a blanket layer), the patternable layer 222 may be etched to form a number of patterns, and those patterns formed in the patternable layer 222 are then transferred to the first dielectric material 220 through at least one etching process. The etching process forming the openings 223-225 may be anisotropic and/or isotropic.

In various embodiments, the first dielectric material 220 includes at least one insulation material, which can electrically isolate neighboring active structures (e.g., metal electrodes which will be formed below) from each other. The insulation material may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used. An anneal process may be performed once the insulation material is formed. Following the deposition of the first dielectric material 220 and the patternable layer 222 with patterns, a dry etch or a wet etch process including, e.g., dilute hydrofluoric (DHF) acid, may be performed to etch the first dielectric material 220.

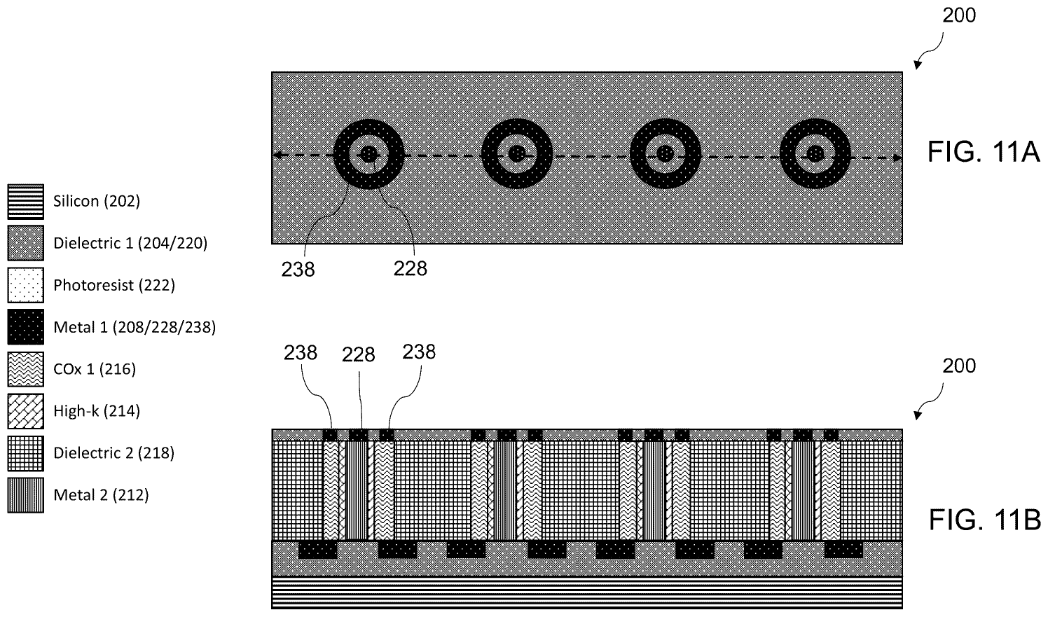

Corresponding to operation 120 of FIG. 1, FIG. 11A is a top view of the semiconductor device 200 in which a number of second metal electrodes 238 and a number of third metal electrodes 228 are formed in the first dielectric material 220 at one of the various stages of fabrication, and FIG. 11B is a corresponding cross-sectional view of the semiconductor device 200, in accordance with various embodiments.

After forming the openings 223 and 225, the patternable layer 222 is removed. Next, the openings 223 and 225 are filled with another first metal material. The first metal material may include copper, aluminum, or the like. The first metal material may be deposited by CVD, physical vapor deposition (PVD), atomic layer deposition (ALD), and/or other suitable metal filling process. Next, a polishing or planarization process (e.g., a chemical mechanical polishing (CMP) process) may be performed to remove excessive first metal material until a coplanar surface is formed by the third metal electrodes 228, the second metal electrodes 238, and the first dielectric material 220. In various embodiments, the third metal electrodes 228 can inherit the dimensions and profiles of the third openings 223 and the second metal electrodes 238 can inherit the dimensions and profiles of the second openings 225, and thus, each of the second metal electrodes 238 may also have a ring-based shape enclosing a corresponding one of the third metal electrodes 228, as shown in the top view of FIG. 11A.

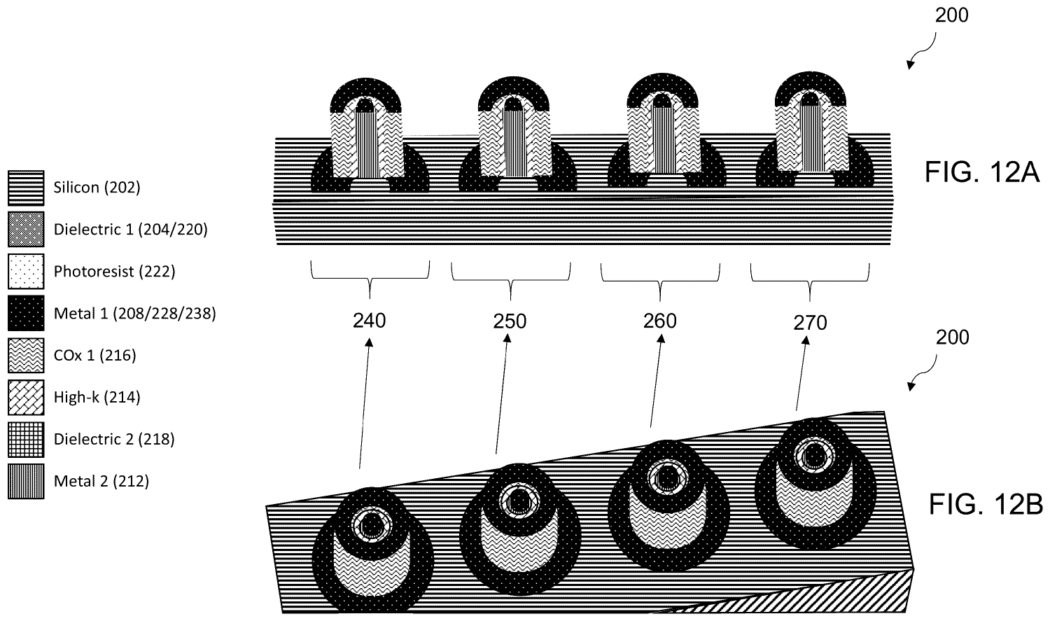

Upon forming the metal electrodes 228 and 238, a number of vertical transistors can be formed or otherwise defined. For example, in perspective views of the semiconductor device 200 shown in FIGS. 12A-B where the first dielectric materials 204 and 220 and the second dielectric material 218 are omitted simply for the sake of clarity, the semiconductor device 200 includes transistors 240, 250, 260, and 270. Each of the transistors 240 to 270 includes a first metal electrode 208 in electrical contact with the first end of a conductive oxide layer 216 and a second metal electrode 238 in electrical contact with the second end of the conductive oxide layer 216, wherein the conductive oxide layer 216 functions as a channel of the corresponding transistor. Further, each transistor has a corresponding metal structure 212 functioning as a gate, which is wrapped by a gate dielectric layer 214, which is further wrapped by a conductive oxide layer 216. In various embodiments, the gate (metal structure 212) is in electrical contact with a third metal electrode 228.

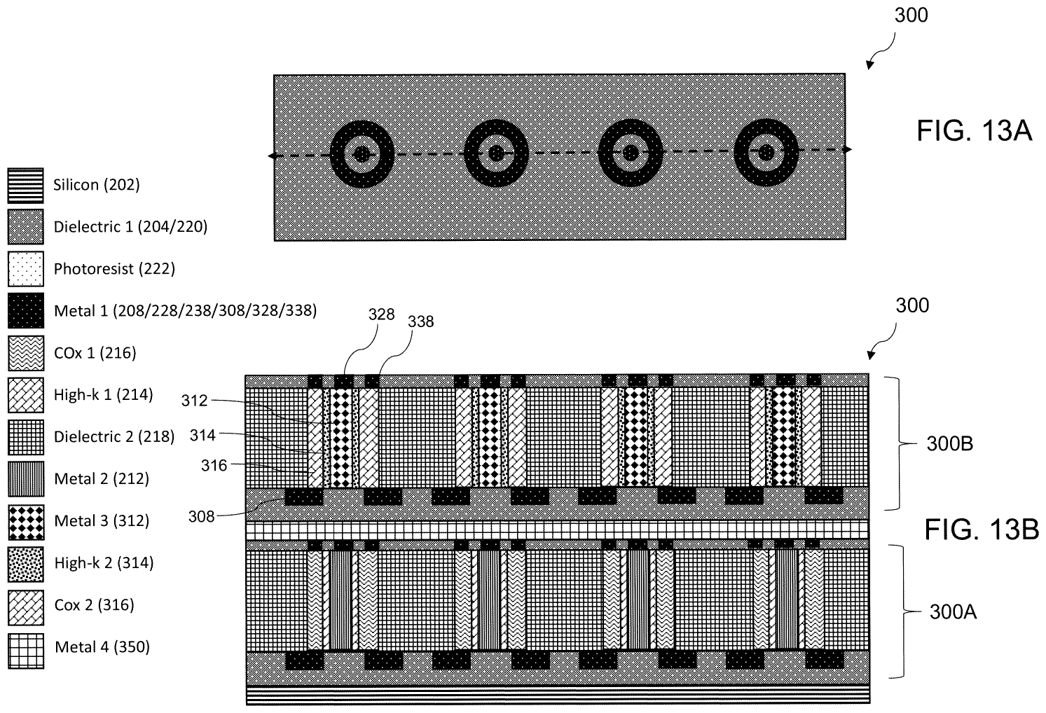

By repeating operations 102 to 120 of the method 100 (FIG. 1), a stacked transistor structure can be formed. FIG. 13A illustrates a top view of such a stacked transistor structure (e.g., a semiconductor device 300) including two semiconductor devices, 300A and 300B stacked on top of one another, and FIG. 13B is a corresponding cross-sectional view of the semiconductor device 300, in accordance with various embodiments.

For example, the semiconductor device 300A is substantially similar to the semiconductor device 200 as shown in FIGS. 12A-B, and thus, the discussion will not be repeated. Also similar to the semiconductor device 200, the semiconductor device 300B, stacked on top of the semiconductor device 300A, has a number (e.g., 4) of transistors laterally arranged with each other. Each of the transistors has a first metal electrode 308 in electrical contact with the first end of a conductive oxide layer 316 and a second metal electrode 338 in electrical contact with the second end of the conductive oxide layer 316, wherein the conductive oxide layer 316 functions as a channel of the corresponding transistor. Further, each transistor has a corresponding metal structure 312 functioning as a gate, which is wrapped by a gate dielectric layer 314, which is further wrapped by a conductive oxide layer 316. In various embodiments, the gate (metal structure 312) is in electrical contact with a third metal electrode 328. In various embodiments, the transistors of the semiconductor device 300A and 300B may have different conductive types, causing the semiconductor device 300 to form a complementary field-effect-transistor. In some embodiments, the transistors of the semiconductor device 300A may be electrically coupled to each other through one or more metal routing structures 350.

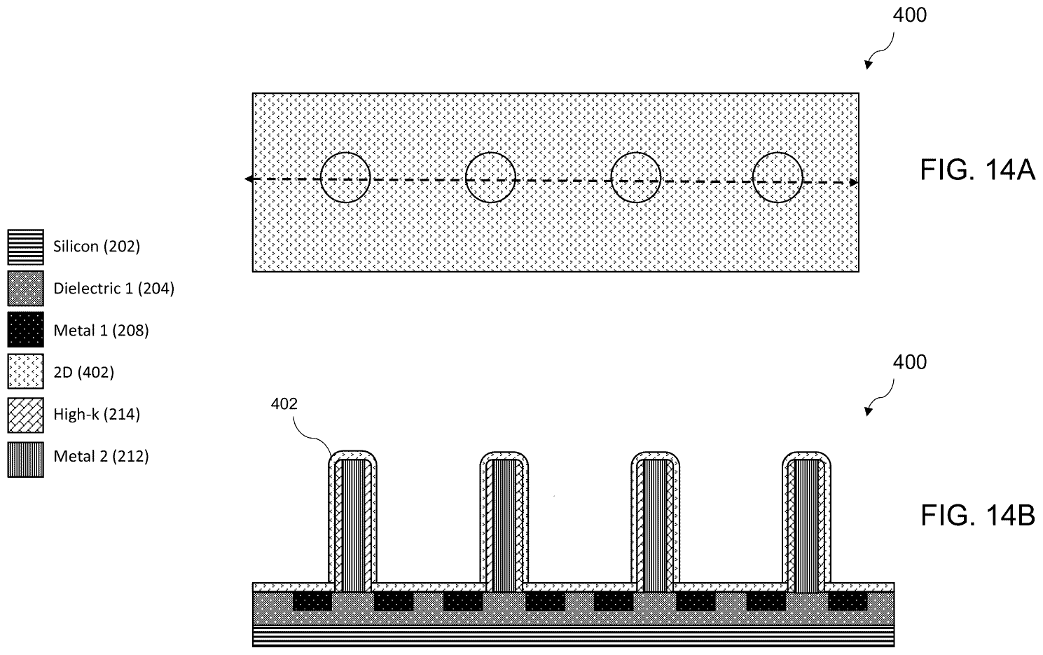

In some other embodiments, operation 114 (FIG. 1) of forming a channel layer may include multiple steps to cause the channel layer to have a stack of multiple layers. FIGS. 14A to 19B illustrate another semiconductor device 400 having a number of transistors, each of which has its channel layers formed as a multi-layer stack. The semiconductor device 400 is substantially similar to the semiconductor device 200 except that the channel layer of the semiconductor device 400, in addition to a conductive oxide layer, may include a two-dimensional material. Both the conductive oxide layer and two-dimensional material may collectively serve as a conductive channel of each of the transistors. Thus, the following discussions of semiconductor device 400 will be focused on the difference, and some reference numerals used for the semiconductor device 200 will be reused.

Referring first to FIGS. 14A and 14B, a top view and a cross-sectional view of the semiconductor device 400 during a first step of operation 114 are illustrated, respectively, in accordance with various embodiments. In this first step, a two-dimensional (2D) material 402 is formed over the workpiece (which includes the patterned gate dielectric layer 214 around the vertical metal structure 212).

The 2D material 402 can include, but is not limited to, graphene, transition metal dichalcogenides (TMDs), WS₂, WSe₂, WTe₂, MoS₂, MoSe₂, MoTe₂, HfS₂, ZrS₂, TiS₂, GaSe, InSe, phosphorene, among others. The 2D material 402, as described herein, may be deposited by an atomic layer deposition (ALD) process and may be 5-15 angstroms thick, the thinness lending to their name—2D material. Other deposition techniques may also be used, including but not limited to chemical vapor deposition (CVD), physical vapor deposition (PVD), and plasma-enhanced deposition techniques. The 2D material 402 may be annealed during or after the device formation process to recrystallize or grow the crystals and thereby improve electrical characteristics.

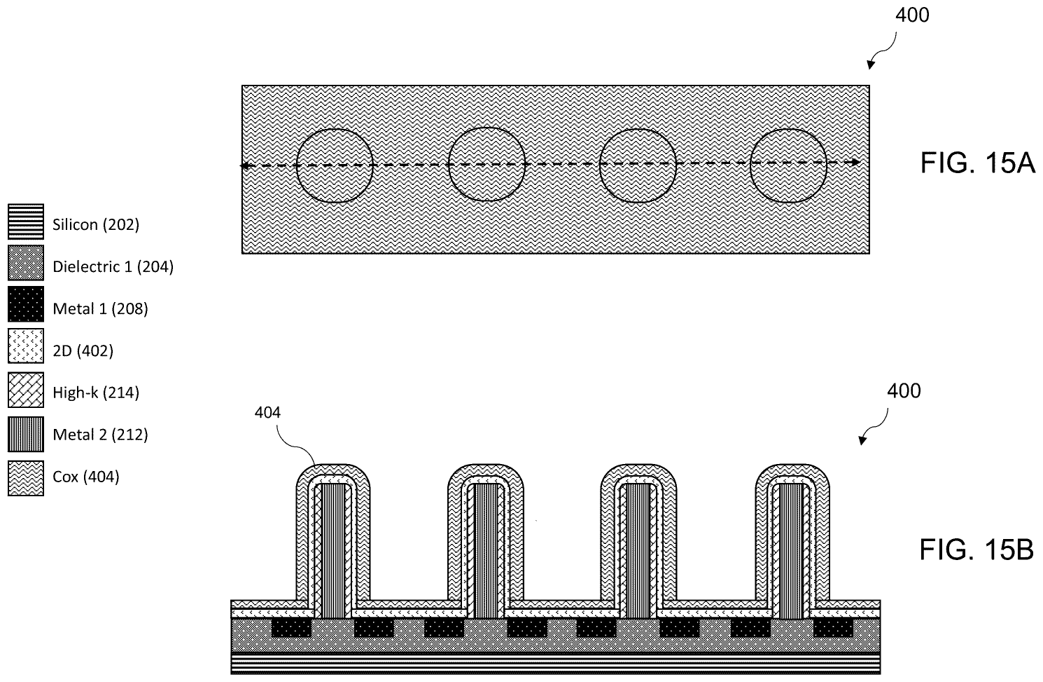

Referring next to FIGS. 15A and 15B, a top view and a cross-sectional view of the semiconductor device 400 during a second step of operation 114 are illustrated, respectively, in accordance with various embodiments. In this second step, a conductive oxide layer 404 is formed over the workpiece (which includes the 2D material 402 around the vertical metal structure 212).

In various embodiments, the conductive oxide layer 404 may be first formed as a blanket layer (e.g., overlaying the top surface of the metal structure 212 and extending along sidewalls of the metal structure 212) followed by a patterning process, which will be discussed below. Example materials of the conductive oxide layer 404 includes, but are not limited to, indium gallium zinc oxide (IGZO), indium tin oxide (ITO), indium zinc oxide (IZO), indium tungsten oxide (IWO), or combinations thereof. In some embodiments, the conductive oxide layer 404 may be formed using, for example, CVD, PECVD, LPCVD, and the like. Further, the conductive oxide layer 404 may be doped through one or more annealing processes to have a certain conductive type, e.g., n-type or p-type.

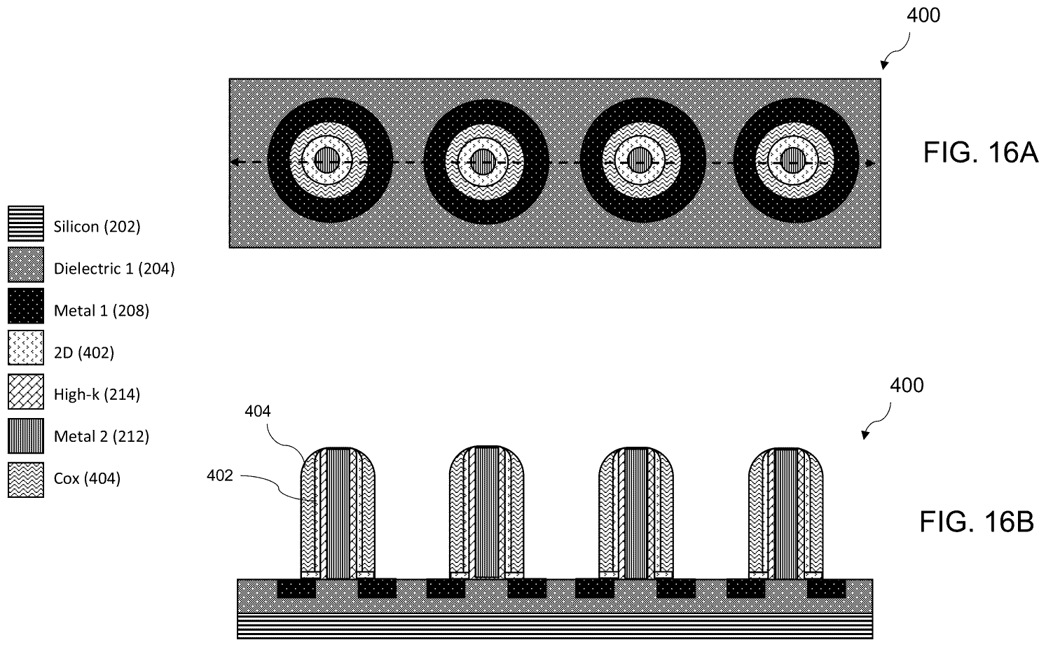

Referring next to FIGS. 16A and 16B, a top view and a cross-sectional view of the semiconductor device 400 during a third step of operation 114 are illustrated, respectively, in accordance with various embodiments. In this third step, the 2D material 402 and the conductive oxide layer 404 are patterned through one or more directional (e.g., vertical) etching process. Consequently, the patterned 2D material 402 may present an L-shaped profile having a lateral portion and a vertical portion, each of which is in contact with the patterned conductive oxide layer 404. Further, the top surface of the metal structure 212 can be exposed.

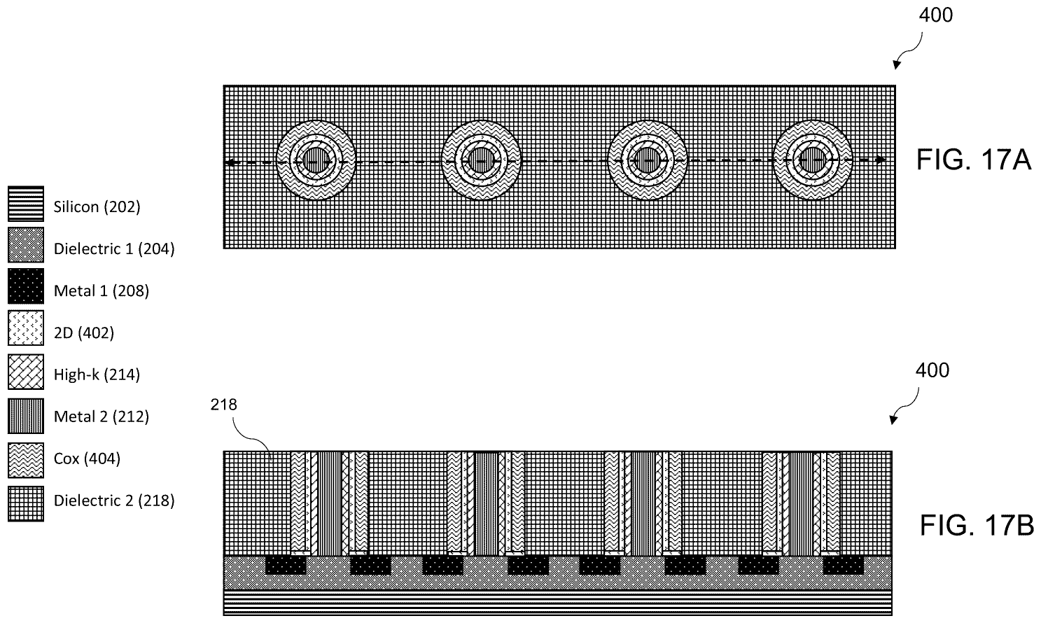

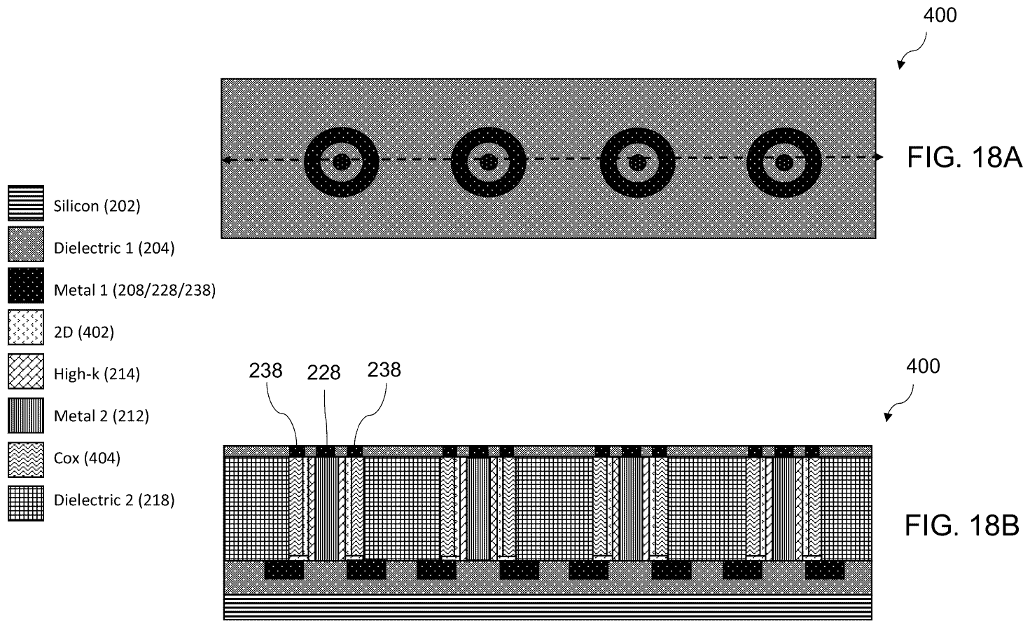

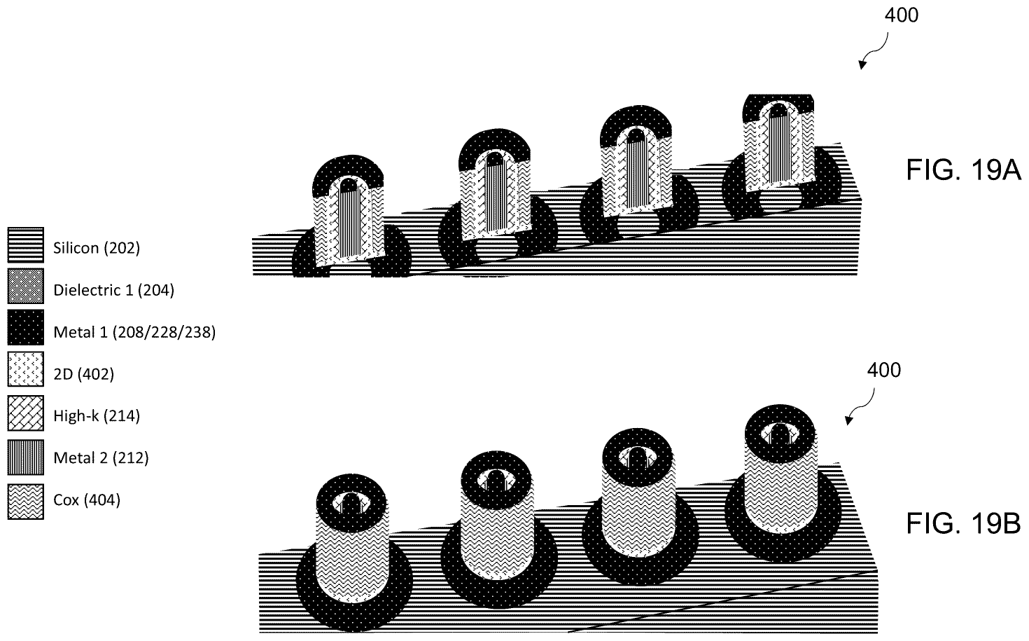

Similarly, following operation 114, second dielectric material 218 is formed over the workpiece (operation 116). FIGS. 17A and 17B illustrate a top view and a cross-sectional view of the semiconductor device 400 during operation 116, respectively, in accordance with various embodiments. Still similarly, following operation 116, a number of second metal electrodes 238 and a number of third metal electrodes 228 are formed over the metal structure 212 (operation 120). FIGS. 18A and 18B illustrate a top view and a cross-sectional view of the semiconductor device 400 during operation 118, respectively, in accordance with various embodiments. Perspective views of the semiconductor device 400, where the first dielectric materials 204 and 220 and the second dielectric material 218 are omitted simply for the sake of clarity, are shown in FIGS. 19A and 19B.

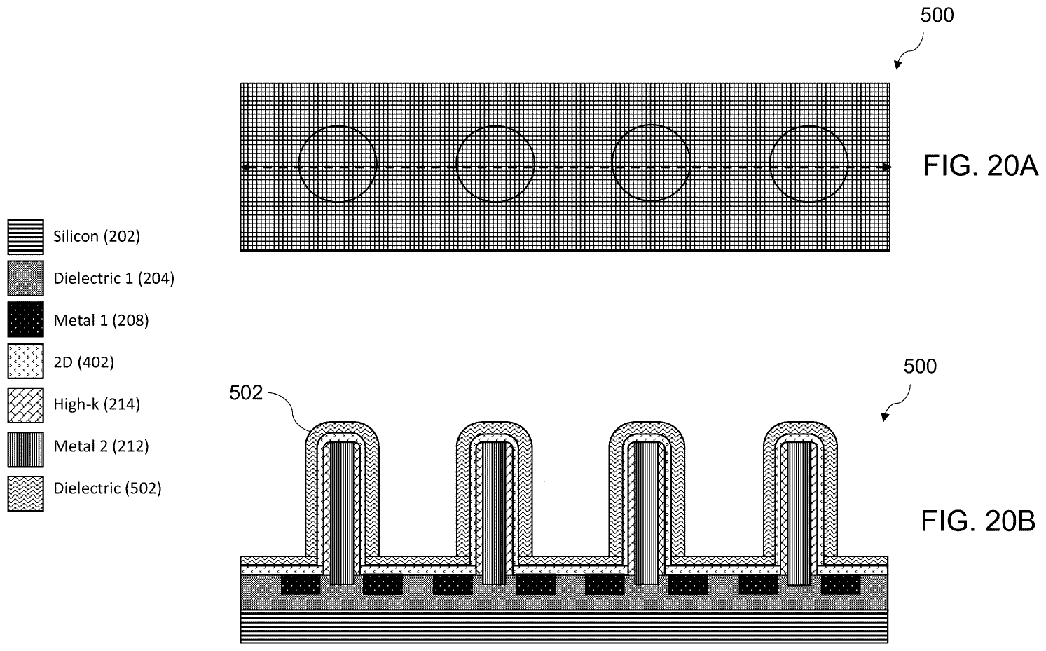

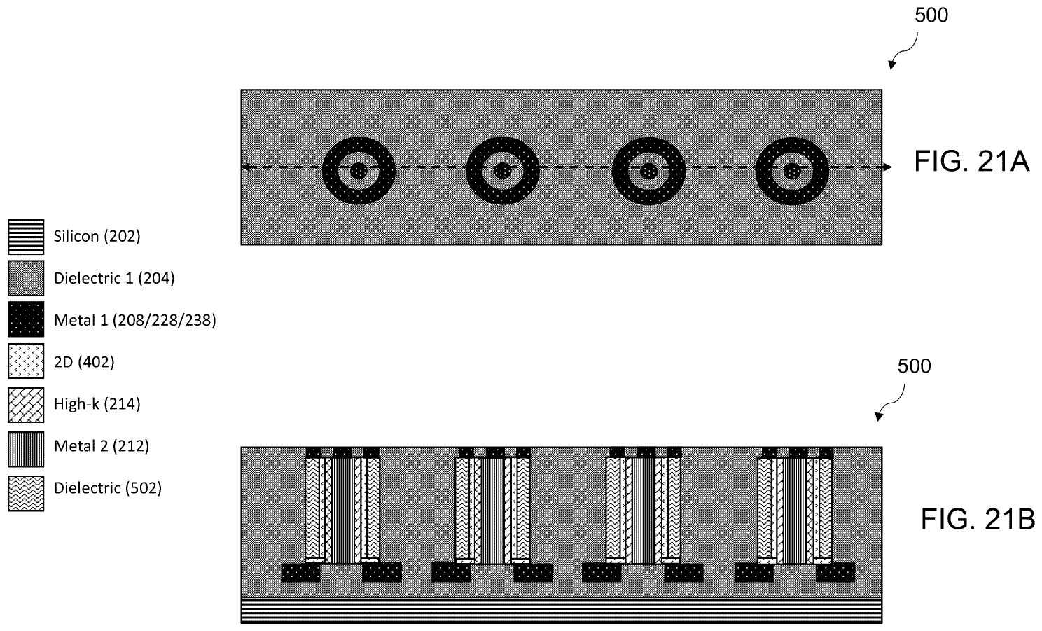

Still in some other embodiments, operation 114 (FIG. 1) of forming a channel layer may include multiple steps to cause the channel layer to have a stack of multiple layers. FIGS. 20A to 21B illustrate yet another semiconductor device 500 having a number of transistors, each of which has its channel layers formed as a multi-layer stack. The semiconductor device 500 is substantially similar to the semiconductor device 400 except that the channel layer of the semiconductor device 500 may include a “stand-alone” two-dimensional material and a dielectric layer. Only the two-dimensional material may serve as a conductive channel of each of the transistors, while the dielectric layer may serve as a protection layer while patterning the two-dimensional material. Thus, the following discussions of semiconductor device 500 will be focused on the difference, and some reference numerals used for the semiconductor device 400 will be reused.

Following the formation of the 2D material 402, a dielectric layer 502 is formed over the workpiece (which includes the 2D material 402 around the vertical metal structure 212). FIGS. 20A and 20B illustrate a top view and a cross-sectional view of the semiconductor device 500, respectively, in accordance with various embodiments. The dielectric layer 502 can protect the underlying 2D material 402 during a patterning process. After the patterning process, the 2D material 402 may be formed with an L-shaped profile, followed by several operations discussed above to form second and third metal electrodes. FIGS. 21A and 21B illustrate a top view and a cross-sectional view of the semiconductor device 500 upon such second and third metal electrodes, 228 and 238, being formed, respectively, in accordance with various embodiments.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features discussed only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence has any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A semiconductor device, comprising:
a transistor structure comprising:
a metal structure extending along a vertical direction;
a gate dielectric layer around the metal structure;
a channel layer around the gate dielectric layer;
a first metal electrode disposed below the metal structure and in electrical contact with a first end of the channel layer;
a second metal electrode disposed above the metal structure and in electrical contact with a second end of the channel layer; and
a third metal electrode disposed above and in electrical contact with the metal structure.

2. The semiconductor device of claim 1, further comprising:
a second transistor structure disposed above the transistor structure and comprising:
a second metal structure extending along the vertical direction;
a second gate dielectric layer around the second metal structure;
a second channel layer around the second gate dielectric layer;
a fourth metal electrode disposed below the second metal structure and above the first metal structure, and in electrical contact with a first end of the second channel layer;
a fifth metal electrode disposed above the second metal structure and in electrical contact with a second end of the second channel layer; and
a sixth metal structure disposed above and in electrical contact with the second metal structure.

3. The semiconductor device of claim 2, wherein the channel layer and second channel layer have respectively different conductive types.

4. The semiconductor device of claim 1, wherein the first metal electrode and second metal electrode are each formed in a ring-based shape.

5. The semiconductor device of claim 1, wherein the channel layer essentially consists of a conductive oxide material.

6. The semiconductor device of claim 1, wherein the channel layer further comprises:
a two-dimensional material around the gate dielectric layer; and
a conductive oxide material around the two-dimensional material.

7. The semiconductor device of claim 6, wherein the two-dimensional material has a vertical portion and a horizontal portion, both of which are in physical contact with the conductive oxide material.

8. The semiconductor device of claim 7, wherein the channel layer electrically connects to the first metal electrode with the horizontal portion of the two-dimensional material, and electrically connects to the second metal electrode with both the conductive oxide and the vertical portion of the two-dimensional material.

9. The semiconductor device of claim 1, wherein the channel layer further comprises:
a two-dimensional material around the gate dielectric layer; and
a dielectric material around the two-dimensional material.

10. The semiconductor device of claim 9, wherein the two-dimensional material has a vertical portion and a horizontal portion, both of which are in physical contact with the dielectric material.

11. The semiconductor device of claim 10, wherein the channel layer electrically connects to the first metal electrode with the horizontal portion of the two-dimensional material, and electrically connects to the second metal electrode with the vertical portion of the two-dimensional material.

12. A semiconductor device, comprising:
a transistor structure comprising:
a metal structure extending along a vertical direction;
a gate dielectric layer around the metal structure;
a channel layer around the gate dielectric layer;
a first metal electrode formed in a first ring-based shape, wherein a top surface of the first metal electrode is in electrical contact with a first end of the channel layer;
a second metal electrode formed in a second ring-based shape, wherein a bottom surface of the second metal electrode is in electrical contact with a second end of the channel layer; and
a third metal electrode surrounded by the second metal structure and in electrical contact with the metal structure.

13. The semiconductor device of claim 12, wherein the channel layer further comprises:
a two-dimensional material around the gate dielectric layer; and
a conductive oxide material around the two-dimensional material,
wherein the two-dimensional material has a vertical portion and a horizontal portion, both of which are in physical contact with the conductive oxide.

14. The semiconductor device of claim 13, wherein the channel layer electrically connects to the first metal electrode with the horizontal portion of the two-dimensional material, and electrically connects to the second metal electrode with the vertical portion of the two-dimensional material.

15. The semiconductor device of claim 12, wherein the channel layer further comprises:
a two-dimensional material around the gate dielectric layer; and
a dielectric material around the two-dimensional material.

16. The semiconductor device of claim 15, wherein the channel layer electrically connects to the first metal electrode with the horizontal portion of the two-dimensional material, and electrically connects to the second metal electrode with the vertical portion of the two-dimensional material.

17. A method for fabricating semiconductor devices, comprising:
forming a first metal electrode on a substrate;
forming a metal structure surrounded by the first metal electrode, wherein the metal structure extends along a vertical direction;
forming a gate dielectric layer around the metal structure;
forming a channel layer around the gate dielectric layer, wherein a first end of the channel layer is in electrical contact with the first metal electrode;
forming a second metal electrode above the metal structure, wherein a second end of the channel layer is in electrical contact with the second metal structure; and
forming a third metal electrode surrounded by the second metal electrode, wherein the third metal electrode is in electrical contact with the metal structure.

18. The method of claim 17, wherein the first metal electrode and second metal electrode are each formed in a ring-based shape.

19. The method of claim 17, wherein the step of forming a channel layer comprises:
depositing a two-dimensional material over the substrate;
depositing a conductive oxide material over the two-dimensional material; and
directionally etching the two-dimensional material and the conductive oxide to form the channel layer.

20. The method of claim 17, wherein the step of forming a channel layer comprises:
depositing a two-dimensional material over the substrate;
depositing a dielectric material over the two-dimensional material; and
directionally etching the two-dimensional material and the dielectric material to form the channel layer.
